(19) United States
(12) Patent Application Publication
(10) Pub. No.: US 2010/0044839 A1
(43) Pub. Date: Feb. 25, 2010

(54) SEMICONDUCTOR DEVICE AND MANUFACTURING METHOD THEREOF

(75) Inventors: Kikuo Okada, Saitama (JP); Kojiro Kameyama, Gunma (JP)

Correspondence Address: MORRISON & FOERSTER LLP, 1650 TYSONS BOULEVARD, SUITE 400, MCLEAN, VA, 22102, US

(73) Assignees: Sanyo Electric Co., Ltd., Osaka (JP); Sanyo Semoconductor Co., Ltd., Ora-Gun (JP)

(21) Appl. No.: 12/445,251

(22) PCT Filed: Oct. 12, 2007
(86) PCT No.: PCT/JP2007/070399

§ 371 Date: May 27, 2009

(30) Foreign Application Priority Data
Oct. 13, 2006 (JP) 2006-280556

(51) Int. Cl. H01L 29/06; H01L 21/04

(52) U.S. Cl. 257/622; 438/478; 257/E21.04; 257/E29.005

(57) ABSTRACT

Provided are a semiconductor device and a method of manufacturing the same. In semiconductor devices of the conventional technologies, the chip size is increased when a breakdown voltage is increased. In the semiconductor device of this invention, an end of a pn junction interface (5) of a collector region (2) and a base region (3) is formed of a mesa groove (6) made of a trench. Thus, the chip size is not increased even when the mesa groove (6) is deeply formed to increase the breakdown voltage.

### REFERENCE TO RELATED APPLICATIONS

This application is a national stage application under 35 USC 371 of International Application No. PCT/JP2007/070399, filed Oct. 12, 2007, which claims the priority of Japanese Patent Application No. 2006-280556, filed Oct. 13, 2006, the contents of which prior applications are incorporated herein by reference.

### FIELD OF THE INVENTION

The present invention relates to a semiconductor device and a manufacturing method thereof. In particular, the present invention relates to a semiconductor device with a mesa structure capable of achieving a higher breakdown voltage without increasing a chip size, and a manufacturing method thereof.

### BACKGROUND OF THE INVENTION

When a semiconductor device typified by, for example, a diode, a bipolar transistor, a MOSFET, an IGBT, and the like includes a curvature portion 105a at a pn junction between a low-concentration n type semiconductor layer 102a formed on a semiconductor substrate 101, and a high-concentration p type semiconductor layer 103a formed on the low-concentration n type semiconductor layer 102a, an electric field is more easily concentrated on the curvature portion 105a than on a flat portion 105b upon application of reverse voltage. This may cause an avalanche breakdown in the curvature portion 105a at a voltage lower than a designed breakdown voltage. To deal with this problem, various breakdown voltage structures have been devised so far to achieve a higher breakdown voltage.

A breakdown voltage structure of a conventional technology will be hereinafter described with an example of a transistor. Hereinbelow, as shown in FIGS. 19 and 20, the transistor includes an n− type collector region 102 formed on an n+ type semiconductor substrate 101, a p type base region 103 formed on a main top surface of the collector region 102, and an n+ type emitter region 104 formed on a main top surface of the base region 103. A thermal oxide film 107 is formed on a top surface of the transistor. Moreover, the transistor has a structure provided with a collector electrode 109, a base electrode 110, and an emitter electrode 111 each connected to the corresponding region.

Firstly, a guard ring structure will be described as an example of the breakdown voltage structure of the conventional technology. FIG. 19 shows a transistor with the guard ring structure. The structure of the transistor is the same as described above. Then, in the guard ring structure, a p type guard ring 106a is provided at an outer periphery of the base region 103. As a result, a depletion layer is extended in a horizontal direction, thereby relaxing an electric field at the curvature portion 105a of the pn junction.

Next, a mesa structure will be described as another example of the breakdown voltage structure of the conventional technology. FIG. 20 shows a transistor with the mesa structure. The structure of the transistor is the same as described above. Then, in the mesa structure, a mesa groove 106 extending over the pn junction interface between the base region 103 and the collector region 102 is formed at the periphery of the base region 103 so as not to form the curvature portion 105a at the pn junction interface. Subsequently, the mesa groove 106 is coated with a passivation film 108. As a result, the pn junction is formed of only a flat portion 105b, and thus an electric field concentration does not occur locally.

As a related technical document, for instance, Japanese Patent Application Publication No. 2003-347306 is known.

However, in the breakdown voltage structure of the conventional technology, the size of an element needs to be increased to achieve the higher breakdown voltage.

To be specific, as shown in FIG. 19, to achieve the higher breakdown voltage, the guard ring structure is required to have an increased number of the guard rings 106a, and to cause the depletion layer formed near the pn junction to extend in the horizontal direction. In other words, when the guard ring structure is employed, the size of the element is made considerably larger than that of the operating region by the size of the guard rings 106a serving as a peripheral region.

On the other hand, as shown in FIG. 20, in order to prevent the depletion layer formed near the pn junction from being exposed from an end of the element after passing through below the mesa groove 106, the mesa structure needs to be formed deeper than the pn junction at least by the depth equal to an extension of the depletion layer. In particular, to achieve the higher breakdown voltage, the impurity concentration of the collector region 102 needs to be lowered so that the depletion layer formed near the pn junction can be further extended toward the collector region 102. In this case, the mesa groove 106 needs to be formed much deeper, in response to the further extension of the depletion layer. However, in the mesa structure of the conventional technology, the mesa groove 106 is formed by isotropic etching. For this reason, the diameter of the mesa groove 106 is increased depending on the depth of the mesa groove 106, so that the size of an element is made larger than that of the operating region. For example, when the mesa groove 106 is formed to have a depth of 100 μm, the diameter of the mesa groove 106 is also increased by 100 μm in the lateral direction.

In addition, the depletion layer is formed perpendicularly to the mesa groove 106. For this reason, in the mesa structure of the conventional technology, an electric field is concentrated on an end portion of the base region 103. Here, a high-concentration p type impurity is added to the base region 103. Thus, such a mesa structure has limitations to the higher breakdown voltage.

### SUMMARY OF THE INVENTION

In view of the above, a semiconductor device according to the present invention is characterized by including: a semiconductor substrate; a first-conductivity-type semiconductor layer which is provided on the semiconductor substrate, and which includes a first side surface and a second side surface at an inner side of the first side surface; and a second-conductivity-type semiconductor layer which is provided on the first-conductivity-type semiconductor layer, and which includes a third side surface, the semiconductor device characterized in that: an operating region which includes a pn junction interface formed between the first-conductivity-type semiconductor layer and the second-conductivity-type semiconductor layer includes one end surface made of the second side surface and the third side surface; and the end surface is a surface substantially perpendicular to the pn junction interface.

In addition, a manufacturing method of a semiconductor device according to the present invention is characterized by including the steps of: preparing a substrate provided with a first-conductivity-type semiconductor layer on a semiconductor substrate, forming a second-conductivity-type semiconductor layer on the first-conductivity-type semiconductor layer, and forming an operating region; performing anisotropic etching to form a trench such that the trench is located at an outer peripheral end of the operating region, and reaches to a part of the first-conductivity-type semiconductor layer from a top surface of the second-conductivity-type semiconductor layer; and coating inside of the trench with an insulating film.

In the present invention, a mesa groove is formed of a trench or a sidewall and a bottom portion of the trench. For this reason, even if the depth of the mesa groove is deep, it is possible to maintain constant the difference between an element size and an operating region.

In addition, a depletion layer extends perpendicularly to the mesa groove. However, in the present invention, since the mesa groove is perpendicular to a pn junction interface, an internal electric field of the depletion layer is formed in a direction parallel to a sidewall of the mesa groove. Thus, the electric field can be prevented from concentrating at an end portion of a base region.

Additionally, in the manufacturing method of a semiconductor device according to the present invention, the mesa groove is coated with a thermal oxide film, and a passivation film is buried in the mesa groove. For this reason, even if the mesa groove is a trench, the coating property of the passivation film does not matter.

Moreover, the passivation film is applied by injecting (dispensing) a thermosetting resin paste into the trench after the formation of the trench. Thus, even if the mesa groove is miniaturized, the thermosetting resin paste can be preferably injected into the trench.

Further, as compared with a case of spin-coating a glass paste, use of the thermosetting resin paste can eliminate the steps of drying, exposure, and development, and thus simplify the manufacturing process.

Furthermore, the trench is formed so that only an upper shoulder portion of the trench gradually can change with a curvature. Thus, the passivation film can be easily applied without lowering the breakdown voltage. In other words, the trench has a shape in which only the upper shoulder portion of the trench gradually spreads with a curvature, so that the injection of the thermosetting resin paste is facilitated.

In addition, wet etching is performed after the formation of the trench, and thereby a damaged layer can be removed. This makes it possible to prevent a leak current at the sidewall of the trench (mesa groove), and improve the coating property of the passivation film or the thermal oxide film for coating the trench.

Moreover, the trench can be formed so that only the upper shoulder portion of the trench gradually can change with a curvature, by appropriately selecting the condition of wet etching. In other words, it is possible to perform the processing of removing the damaged layer and chamfering the upper shoulder portion of the trench in a single wet etching process.

### BRIEF DESCRIPTION OF THE DRAWINGS

FIG. 1A is a diagram showing a section of a semiconductor device according to a first embodiment of the present invention;

FIG. 1B is a diagram showing a plane of the semiconductor device according to the first embodiment of the present invention;

FIG. 2 is a diagram showing a section of a semiconductor device according to a second embodiment of the present invention;

FIG. 3 is a diagram showing a section of a semiconductor device according to a third embodiment of the present invention;

FIG. 4 is a diagram for explaining a breakdown voltage of a mesa structure according to a conventional technology;

FIG. 5 is a diagram for explaining a breakdown voltage of a mesa structure according to a conventional technology;

FIG. 6 is a diagram for explaining a breakdown voltage of a mesa structure according to the present invention;

FIG. 7 is a diagram for explaining a relation between a mesa angle and a breakdown voltage;

FIG. 8 is a diagram showing one section in a step of a manufacturing method of the semiconductor device according to the first embodiment of the present invention;

FIG. 9A is a diagram showing one section in a step of the manufacturing method of the semiconductor device according to the first embodiment of the present invention;

FIG. 9B is a diagram showing one section in a step of the manufacturing method of the semiconductor device according to the first embodiment of the present invention;

FIG. 10A is a diagram showing one section in a step of the manufacturing method of the semiconductor device according to the first embodiment of the present invention;

FIG. 10B is a diagram showing one section in a step of the manufacturing method of the semiconductor device according to the first embodiment of the present invention;

FIG. 11A is a diagram showing one section in a step of the manufacturing method of the semiconductor device according to the first embodiment of the present invention;

FIG. 11B is a diagram showing one section in a step of the manufacturing method of the semiconductor device according to the first embodiment of the present invention;

FIG. 12 is a diagram showing one section in a step of a manufacturing method of the semiconductor device according to the second embodiment of the present invention;

FIG. 13 is a diagram showing one section in a step of a manufacturing method of the semiconductor device according to the third embodiment of the present invention;

FIG. 14A is a diagram showing one section in a step of the manufacturing method of the semiconductor device according to the third embodiment of the present invention;

FIG. 14B is a diagram showing one section in a step of the manufacturing method of the semiconductor device according to the third embodiment of the present invention;

FIG. 15A is a diagram showing one section in a step of the manufacturing method of the semiconductor device according to the third embodiment of the present invention;

FIG. 15B is a side view showing a step of the manufacturing method of the semiconductor device according to the third embodiment of the present invention;

FIG. 16 is a diagram showing one section in a step of the manufacturing method of the semiconductor device according to the third embodiment of the present invention;

FIG. 17 is a diagram showing a section, as another example, of the manufacturing method of the semiconductor device according to the second embodiment of the present invention;

FIG. 18 is a diagram showing a section of a semiconductor device according to a conventional technology;

FIG. 19 is a diagram showing a section of the semiconductor device according to the conventional technology; and

FIG. 20 is a diagram showing a section of the semiconductor device according to the conventional technology.

### DETAILED DESCRIPTION OF THE INVENTION

Hereinafter, a semiconductor device and a manufacturing method thereof according to preferred embodiments of the present invention will be described in detail with reference to the drawings. Note that, a case where the semiconductor device is a bipolar transistor will be described hereinbelow as an example. However, the present invention is applicable in the same way, even if the semiconductor device is a diode, a MOSFET (Metal Oxide Semiconductor Field Effect Transistor), or an IGBT (Insulated GateBipolar Transistor). In other words, the present invention is applicable in the same way, as long as the semiconductor device is required to achieve a high breakdown voltage and includes: a pn junction parallel to a main surface of a semiconductor substrate; and an operating region provided with a so-called discrete active element in which a current path is formed in a direction perpendicular to the main surface of the semiconductor substrate (film thickness direction).

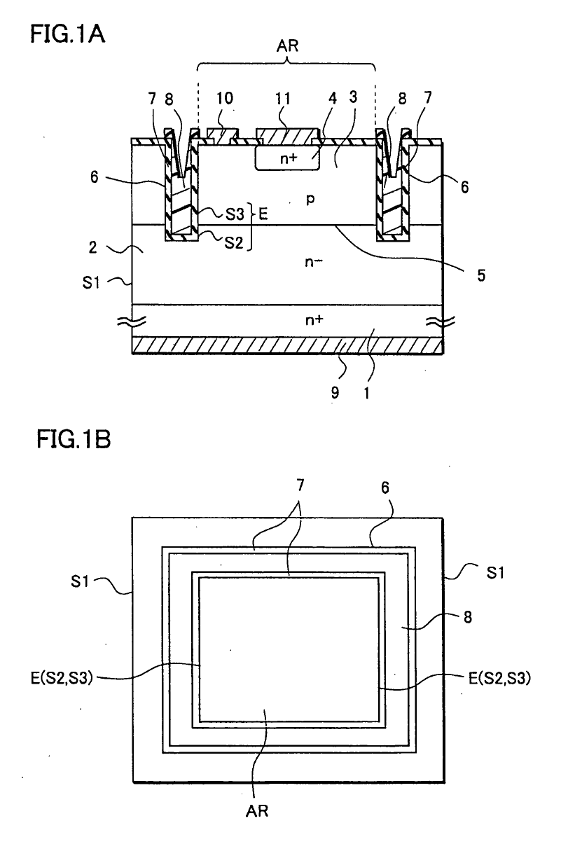

Firstly, a structure of a semiconductor device according to a first embodiment will be described with reference to FIG. 1. FIG. 1A is a section view of the semiconductor device, and FIG. 1B is a plan view of the semiconductor device. Incidentally, in FIG. 1B, a positional relation between an operating region and a mesa groove is shown schematically, and specific details an electrode and an operating region formed on a top surface of the semiconductor device are omitted.

Refer to FIGS. 1A and 1B. The semiconductor device according to this embodiment includes: a semiconductor substrate 1; a first-conductivity-type semiconductor layer 2; a second-conductivity-type semiconductor layer 3; a pn junction interface 5; a first side surface S1; a second side surface S2; a third side surface S3; and an operating region AR.

The semiconductor substrate 1 is an n+ type semiconductor substrate, for example. The first-conductivity-type semiconductor layer (for example, n− type semiconductor layer) 2 and the second-conductivity-type semiconductor layer (for example, p type semiconductor layer) 3 are laminated on the semiconductor substrate 1, so that the pn junction interface 5 is formed between the n− type semiconductor layer 2 and the p type semiconductor layer 3.

The n− type semiconductor layer 2 includes the first side surface S1, and the second side surface S2 provided at an inner side of the first side surface S1. In addition, the p type semiconductor layer 3 includes the third side surface S3. Moreover, the second side surface S2 and the third side surface S3 form a continuous flat surface, i.e. constitute an end surface E.

The operating region AR of this embodiment includes: the p type semiconductor layer 3 having the pn junction interface 5; a part of the n− type semiconductor layer 2; and an impurity diffusion region that is provided, as needed, on a top surface of the p type semiconductor layer 3. Then, the operating region AR includes the end surface E that is substantially perpendicular to the pn junction interface 5. Note that, the semiconductor substrate 1 also serves as a current path actually, and contributes to the operation of the semiconductor device. However, here, a region defined by the end surface E is set as the operating region AR.

To be specific, the bipolar transistor includes: the collector region 2 made of the n− type semiconductor layer formed on the n+ type semiconductor substrate 1; the base region 3 made of the p type semiconductor layer formed on a main top surface of the collector region 2; and an n+ type emitter region 4 formed on a main top surface of the base region 3. Moreover, the bipolar transistor is provided with a collector electrode 9, a base electrode 10, and an emitter electrode 11 each connected to the corresponding region. Note that, in FIG. 1, a basic unit configuration (cell) of the transistor is shown as an outline of the operating region AR. However, the illustrated cell is provided in multiple actually. In addition, the n+ type semiconductor substrate 1 also functions as a part of the collector region.

As shown in FIG. 1B, a mesa groove 6 is provided at the outer periphery of the operating region AR. The mesa groove 6 is formed at the outer periphery of the base region 3 to be deeper than the pn junction interface 5 so as not to form a curvature portion at the pn junction interface 5 formed between the collector region 2 and the base region 3.

The mesa groove 6 is a groove that defines or separates, into a mesa shape, the base region (p type semiconductor layer) 3 and a part of the collector region (n− type semiconductor layer) 2 by a sidewall and a bottom portion of the mesa groove 6. In this embodiment, the mesa groove 6 is a trench formed by anisotropic dry etching. In other words, the end surface E formed of the second side surface S2 and the third side surface S3 is a sidewall of the mesa groove 6.

As a result, the pn junction interface 5 in the operating region AR is a surface substantially perpendicular to the end surface E formed of only a flat portion (see FIG. 1A). Accordingly, the internal electric field of a depletion layer, which extends from the pn junction interface 5 when a reverse voltage is applied to the bipolar transistor, is formed in a direction almost parallel to the end surface E, even in the vicinity of the tip end portion of the pn junction interface 5. Thus, an electric field concentration does not occur locally.

Here, the mesa groove 6 needs to have a depth at least deeper than the pn junction interface 5. However, in this embodiment, since the mesa groove 6 is formed of a trench having a high aspect ratio, an opening diameter of the mesa groove 6 is not widened even if the mesa groove 6 is formed deeper. In other words, it is possible to maintain constant the difference between: the operating region AR which is formed of the emitter region 4, the base region 3 and the collector region 2, and which is defined by the end surface E; and the chip size of a chip having the first side surface S1. Specifically, the mesa groove 6 is formed to have a width of approximately 50 μm and a depth of approximately 100 μm, for example.

Here, the mesa groove 6 is coated with a thermal oxide film 7. In addition, a passivation film 8 is buried in the mesa groove 6 from above the thermal oxide film 7. A thermosetting resin such as polyimide, for example, is used as the passivation film 8. Note that, depending on a desired breakdown voltage, the passivation film 8 may be directly buried in the mesa groove 6 without the thermal oxide film 7 coating the mesa groove 6.

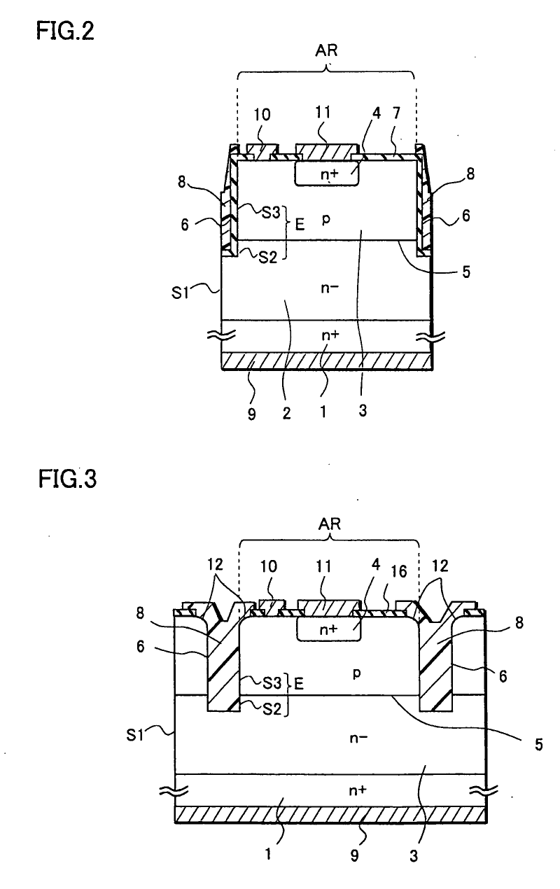

Next, a structure of a semiconductor device according to a second embodiment will be described with reference to FIG. 2.

The basic structure of this embodiment is the same as that of the first embodiment. However, the difference is that a peripheral region outside an operating region AR surrounded by a mesa groove 6 is removed, and each element is separated from the others.

As described above, in the preferred embodiment of the present invention, the mesa groove 6 is formed of a trench. For this reason, as long as the mechanical strength of the semiconductor substrate 1 is maintained, the depth of the mesa groove 6 can be freely designed regardless of the chip size. Consequently, the mesa groove 6 can be formed reliably deeply to a depth where the depletion layer never exceeds the mesa groove 6, and thereby a sufficient breakdown voltage can be obtained.

In addition, a passivation film 8 buried in the mesa groove 6 can reliably prevent the end portion of the mesa groove from being exposed.

With such a shape, the chip size of a chip having a first side surface S1 is almost equal to the size of the operating region AR having an end surface E. Thus, such a shape is suitable for miniaturization.

Next, a structure of a semiconductor device according to a third embodiment will be described with reference to FIG. 3.

The basic structure of this embodiment is also the same as that of the first embodiment. However, the difference is that an upper shoulder portion 12 alone of a mesa groove 6 is formed to gradually spread with a curvature.

Accordingly, since an opening portion alone of the mesa groove 6 spreads, a passivation film 8 can be easily applied even to the mesa groove 6, which achieves miniaturization by forming a trench. In other words, in this embodiment, the coating property of the passivation film 8 coating the mesa groove 6 is improved. Thus, unlike the first and second embodiments, the mesa groove 6 can be directly coated with the passivation film 8 without a thermal oxide film 7 being formed. Incidentally, in this embodiment also, although not illustrated, each element may be separated from the others at the portion of the mesa groove 6 in the same manner as the second embodiment.

Note that, in this embodiment, the mesa groove 6 has a trench shape, except for the upper shoulder portion 12, in the same manner as the first and second embodiments. The opening diameter of the mesa groove 6 is maintained constant regardless of the depth of the mesa groove 6.

Additionally, in the third embodiment, the thermal oxide film 7 may be formed on an inner wall of the mesa groove 6 in the same manner as the first embodiment.

Subsequently, the breakdown voltage characteristics of the above-mentioned semiconductor devices according to the first to third embodiments will be described.

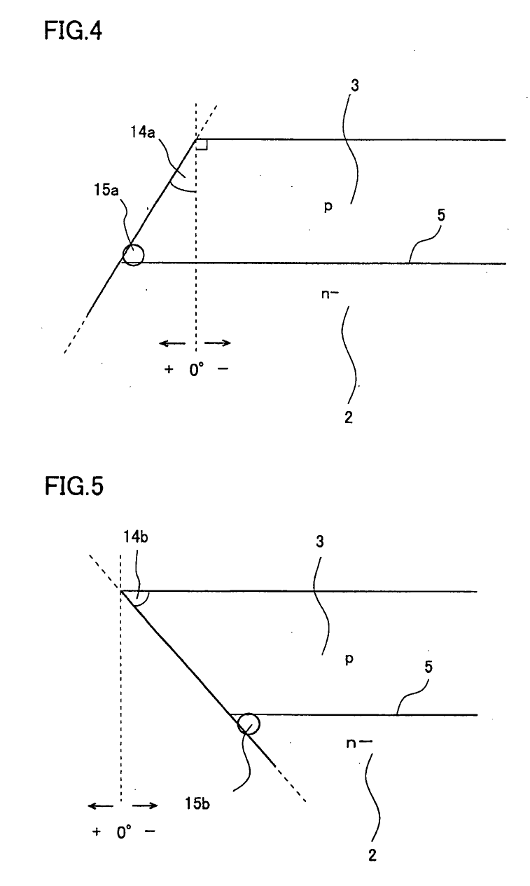

As shown in FIG. 4, in a forward mesa structure (a case where a mesa angle 14a, which is an angle formed between a surface perpendicular to a main surface of the p type semiconductor layer 3 and a sidewall of the mesa groove 6, considerably exceeds 0°), an electric-field concentration portion 15a occurs at an end portion of the base region 3. Here, since a high-concentration p type impurity is added to the base region 3, the electric field strength of the base region 3 is increased. Additionally, an electric field equal to this electric field is generated at the surface (thermal oxide film 7 or passivation film 8) of the mesa groove 6. As a result, the breakdown voltage is reduced.

Meanwhile, as shown in FIG. 5, in a reverse mesa structure (a case where a mesa angle 14b is smaller than 0°), an electric-field concentration portion 15b occurs at an end portion of the collector region 2. Here, the collector region 2 is formed to have a low impurity concentration in order that a depletion layer formed near the pn junction interface 5 is extended toward the collector region 2 to increase the breakdown voltage. Consequently, the electric field strength of the electric-field concentration portion 15b is lower than that of the electric-field concentration portion 15a in the forward mesa structure. Additionally, an electric field equal to this electric field is generated at the surface (thermal oxide film 7 or passivation film 8) of the mesa groove 6. As a result, the breakdown voltage is increased in the reverse mesa structure, as compared with the forward mesa structure.

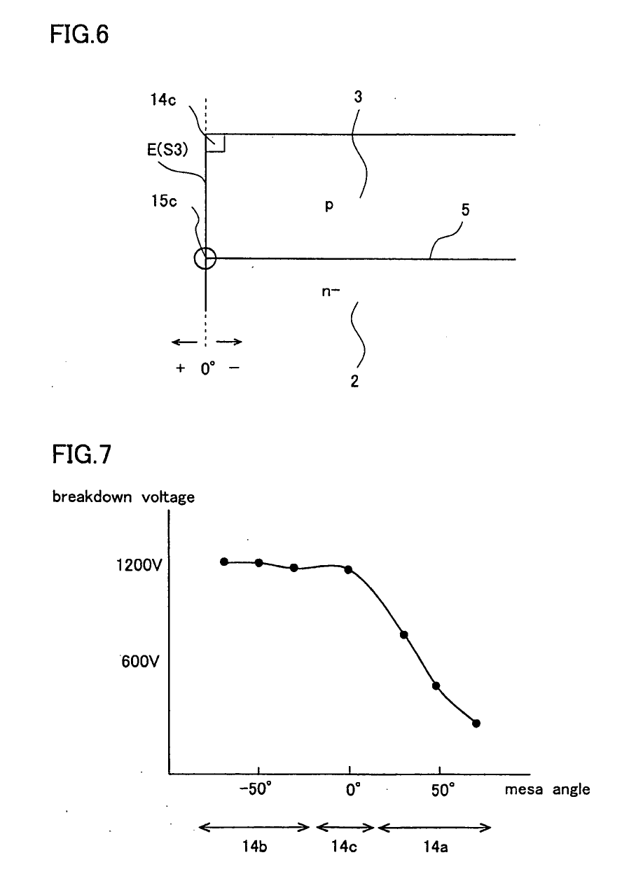

In addition, as shown in FIG. 6, when the mesa groove 6 is formed of a trench and a mesa angle 14c is near 0°, an electric-field concentration portion 15c occurs at an end portion of the pn junction interface 5. Additionally, an electric field equal to this electric field is generated at the surface (thermal oxide film 7 or passivation film 8) of the mesa groove 6.

Here, when the electric field strength of this case is measured, it is found that the electric field strength of this case is almost equal to that of the electric-field concentration portion 14b in the reverse mesa structure. In other words, the breakdown voltage equal to that in the reverse mesa structure is obtained in the semiconductor device according to this embodiment.

To sum up, the relation between the mesa angle and the breakdown voltage is as shown in FIG. 7. It can be seen therefrom that the breakdown voltage greatly changes from the point at which the mesa angle 14 is 0°. In other words, to increase the breakdown voltage, the electric-field concentration portion 15 only needs to be prevented from concentrating at the base region 3.

Additionally, to meet this condition, the mesa groove 6 is not required to be totally inclined steeply in the depth direction. Instead, the mesa groove 6 is required only to have the mesa angle 14 of 0° at the pn junction interface 5. In other words, as shown in FIG. 6, when the end surface E of the operating region AR that includes the pn junction interface 5 is substantially perpendicular (preferably the mesa angle 14 is 0°) to at least the pn junction interface 5, the electric field in the depletion layer extending from the pn junction interface 5 is formed in a direction almost parallel to the sidewall of the mesa groove 6. In other words, the electric field concentration at the base region 3 is relaxed to improve the breakdown voltage.

Accordingly, in the semiconductor device according to the third embodiment, although the upper shoulder portion 12 of the mesa groove 6 spreads with a gradual curvature, the end portion E is substantially perpendicular to the pn junction interface 5. Consequently, the breakdown voltage is equal to those in the first and second embodiments. Moreover, in the semiconductor device according to the third embodiment, the mesa groove 6 is directly coated with the passivation film 8 such as polyimide, without use of the thermal oxide film 7. Thus, the breakdown voltage can be freely designed by changing the material of the passivation film 8.

Furthermore, due to the damage caused by etching and the like, the p type semiconductor layer (base region) 3 is sometimes easily reversed under the influence of outer factors, as compared with the n− type semiconductor layer (collector region) 2. In such a case, the impurity concentration in the vicinity of the third side surface S3 of the p type semiconductor layer 3 should be slightly increased.

Subsequently, a manufacturing method of a semiconductor device according to the first embodiment will be described.

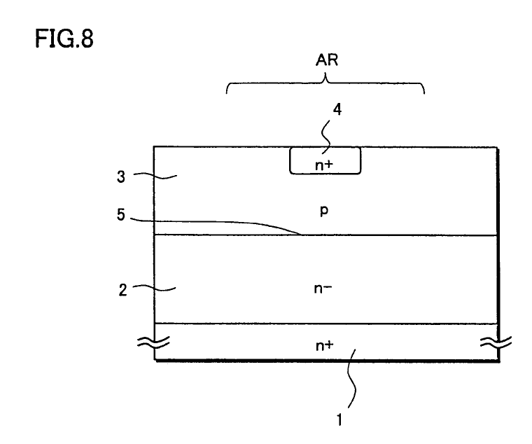

First Step (FIG. 8): a step in which a substrate provided with a first-conductivity-type semiconductor layer on a semiconductor substrate is prepared, a second-conductivity-type semiconductor layer is formed on the first-conductivity-type semiconductor layer, and an operating region is formed.

Firstly, as shown in FIG. 8, an n− type semiconductor layer is laminated on an n+ type semiconductor substrate 1 having a thickness of approximately 200 μm by, for example, epitaxial growth or the like, so as to form a collector region 2. Note that, the collector region 2 may be formed by ion implantation, depending on a film thickness required for the collector region 2. Here, the collector region 2 is required to have a low impurity concentration, in order to increase the breakdown voltage by extending a depletion layer formed near the pn junction interface 5 toward the collector region 2. Then, a base region 3 made of a p type semiconductor layer is formed on the collector region 2. Incidentally, the base region 3 may be formed to have a low impurity concentration near the pn junction interface 5, in order to lower the electric field strength near the pn junction interface 5 of the base region 3. Thereafter, ions of an n type impurity are implanted into a predetermined region of the base region 3, so as to form an emitter region 4.

In this way, an operating region AR made of a part of the collector region 2, the base region 3, and the emitter region 4 is formed. Note that, although not illustrated, an insulating film or the like, which is provided to form the operating region AR, remains on a top surface of the operating region AR, as needed.

In addition, the n+ type semiconductor substrate 1 also functions as a collector region. However, in the description below, the n− type semiconductor layer is called the collector region 2.

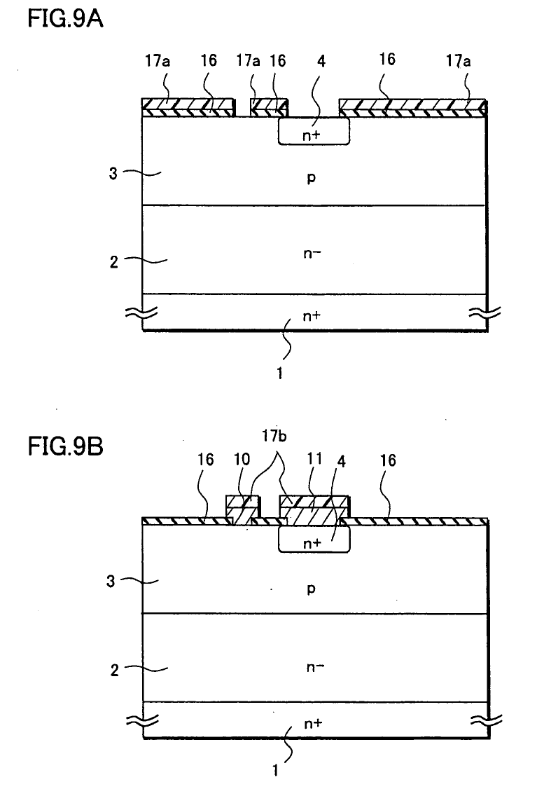

Next, as shown in FIG. 9A, a thermal oxide film 16 is formed on the entire surface, and a photoresist film 17a is formed to have opening portions located at positions corresponding to a base electrode 10 and an emitter electrode 11. Then, the thermal oxide film 16 is etched by using the photoresist film 17a as a mask. Thereafter, the photoresist film 17a is removed.

Refer to FIG. 9B. An electrode material 18 such as Al is deposited on the entire surface by a sputtering method or the like, so that a new photoresist film 17b is formed on the entire surface. After that, the photoresist film 17b is patterned so as to remain at positions corresponding to the base electrode 10 and the emitter electrode 11. Then, the electrode material 18 is etched by using the photoresist film 17b a mask, so as to form the base electrode 10 and the emitter electrode 11.

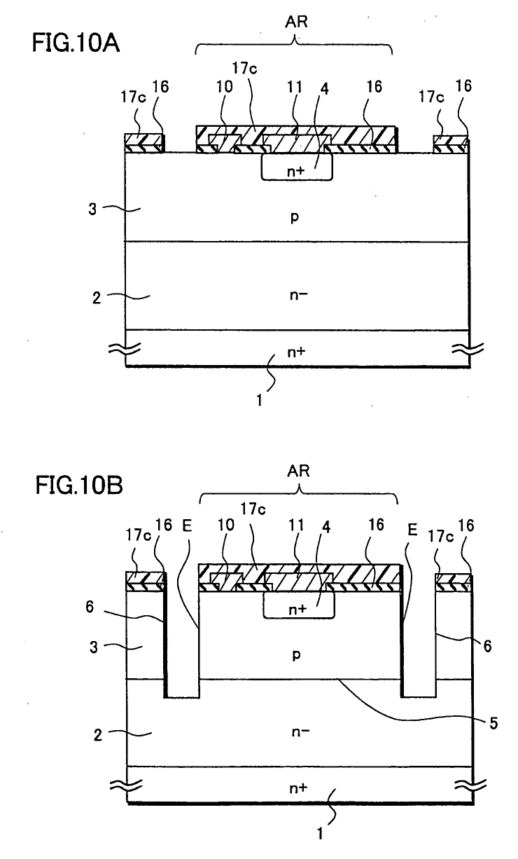

Second Step (FIG. 10): a step in which anisotropic etching is performed to form a trench such that the trench is located at an outer peripheral end of the operating region, and reaches a part of the first-conductivity-type semiconductor layer from a top surface of the second-conductivity-type semiconductor layer.

Firstly, refer to FIG. 10A. After the photoresist film 17b is removed, a new photoresist film 17c is formed. Then, the photoresist film 17c is patterned so as to have an opening portion at the periphery of the operating region AR. After that, etching is performed by using the photoresist film 17c as a mask, so as to remove the thermal oxide film 16 exposed from the opening portion of the photoresist film 17c.

Next, as shown in FIG. 10B, anisotropic etching is performed on the p type semiconductor layer 3 and the n− type semiconductor layer 2, by using the photoresist film 17c and the thermal oxide film 16 as a mask, so that a trench is dug to form a mesa groove 6.

The mesa groove 6 is located at an outer peripheral end of the operating region AR, and defines or separates the operating region AR into a mesa shape. In other words, a sidewall of the mesa groove 6 is an end surface of the operating region AR (see FIG. 1).

As anisotropic etching, employed is dry etching using a CF-based gas and an HBr-based gas, for example. Here, the mesa groove 6 is formed such that the mesa groove 6 is at least deeper than the pn junction interface 5, and that the depletion layer does not exceed the mesa groove 6. In this embodiment, the mesa groove 6 is dug almost perpendicularly. For this reason, even if the mesa groove 6 is formed deeper, the chip size is almost equal to the operating region AR.

Note that, when the mesa groove 6 is formed by dry etching, a top surface of the mesa groove 6 is rough in many cases. Then, the rough top surface of the mesa groove 6 may cause a leak current. For this reason, wet etching is performed on the top surface of the mesa groove 6 to remove the rough top surface alone. Incidentally, in this wet etching, the shape of the mesa groove 6 hardly changes, at least near the pn junction interface 5. In other words, even if wet etching is performed, the angle formed between the mesa groove 6 and the pn junction interface 5 is maintained at substantially 90°. This is because, in the wet etching, the speed of the etching process near the upper portion of the mesa groove 6 greatly varies in the depth direction of the mesa groove 6; however, the degree of exposure to the etching liquid hardly varies near the pn junction interface 5 of the mesa groove 6, and thus the speed of the etching process is substantially the same.

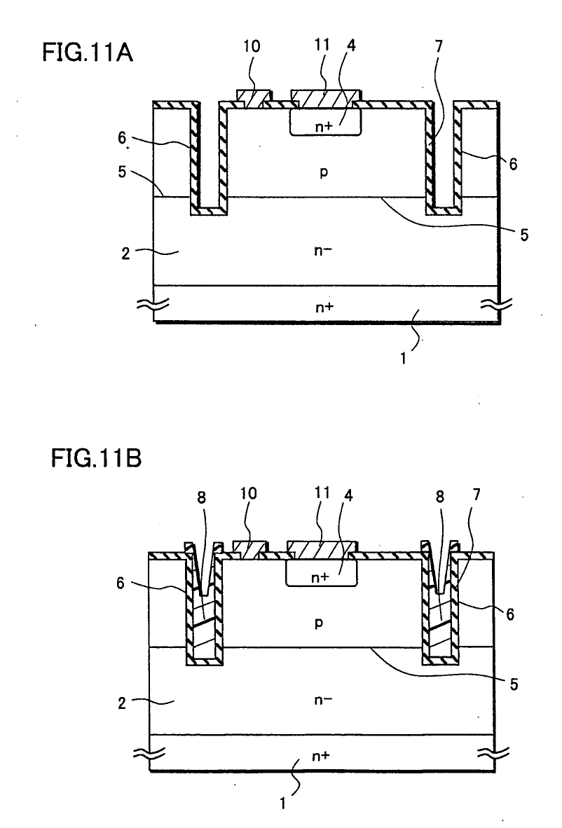

Third Step (FIG. 11): a step in which the inside of a trench is coated with an insulating film.

Firstly, as shown in FIG. 11A, the photoresist film 17c is removed, and a thermal oxide film 7 is formed on the entire surface. Thus, the thermal oxide film 7 is formed on an inner wall of the trench 7.

Moreover, as shown in FIG. 11B, a passivation film 8 is formed so as to be buried in the mesa groove 6 that is coated with the thermal oxide film 7.

Thereafter, as shown in FIG. 1, a collector electrode 9 such as Al is formed at a back surface side of the semiconductor substrate, so as to complete a semiconductor device according to the first embodiment.

As described above, in the manufacturing method of the semiconductor device according to this embodiment, the mesa groove 6 is formed of a trench, and thus the mesa groove 6 can be formed deeper than the pn junction interface 5 without increasing the chip size.

Subsequently, a manufacturing method of a semiconductor device according to the second embodiment will be described.

Firstly, a structure shown in FIG. 1 is formed through the same first to third steps as in the manufacturing method of the semiconductor device according to the first embodiment.

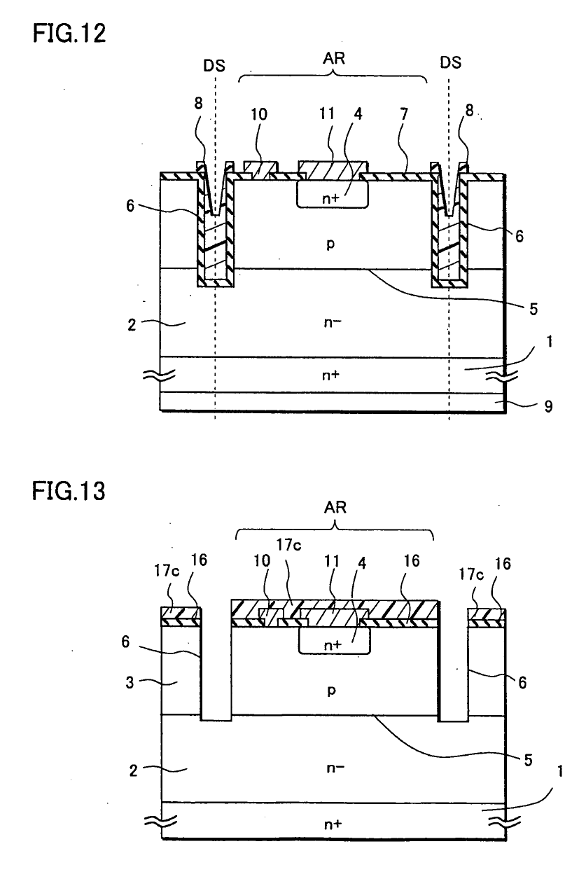

Next, as shown in FIG. 12, dicing is performed along a dicing line DS corresponding to a mesa groove 6, whereby each element is separated from the others at the mesa groove 6. In this case, the chip size is approximately the same as the size of an operating region AR. Incidentally, in the second embodiment, if the depletion layer exceeds the mesa groove 6 from thereunder, the depletion layer is exposed to a chip end. For this reason, in this embodiment, the mesa groove 6 is required to be formed deeper in consideration of the extension of the depletion layer. In this respect, in the preferred embodiment of the present invention, the mesa groove 6 is formed of a trench, and thus the chip size does not become larger even if the depth of the mesa groove 6 becomes deeper.

Subsequently, a manufacturing method of a semiconductor device according to the third embodiment will be described.

Firstly, after the same first step as in the manufacturing method of the semiconductor device according to the first embodiment is performed, a trench is formed by anisotropic dry etching in the second step (see FIG. 10).

In this way, a structure shown in FIG. 13 is formed. Note that, in this embodiment, at this time point, the mesa groove 6 is formed to be shallower than a desired depth.

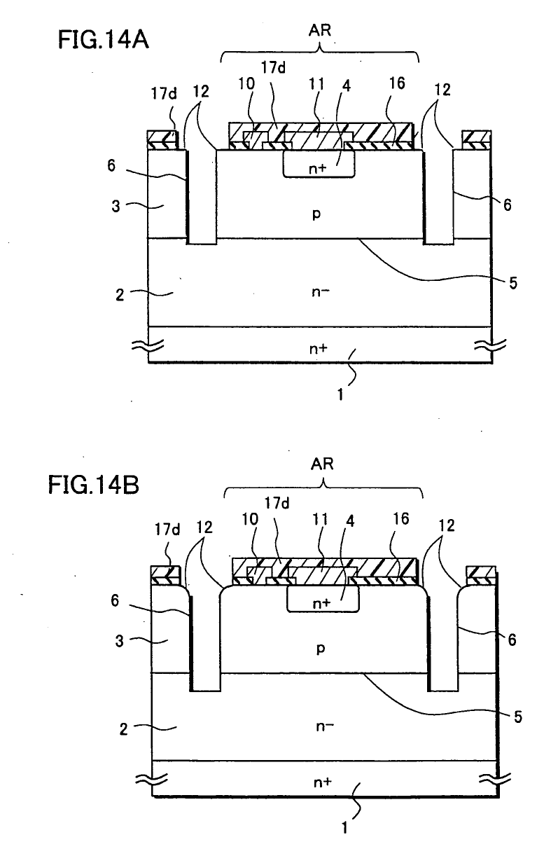

Next, as shown in FIG. 14A, a new photoresist film 17d having an opening portion near an upper shoulder portion 12 of the mesa groove 6 is formed. After that, etching is performed by using the photoresist film 17d as a mask, so as to remove only a thermal oxide film 16 near the upper shoulder portion 12.

Subsequently, as shown in FIG. 14B, additional anisotropic etching is performed by using the photoresist film 17d and the thermal oxide film 16 as a mask. Then, the mesa groove 6 is formed to the desired depth, and concurrently, the upper shoulder portion 12 of the mesa groove 6 is formed with a gradual curvature because the etching speed at this portion is fast. Incidentally, also in this case, wet etching may be added to remove the rough part of a top surface of the mesa groove 6.

Thereafter, in the third step, an insulating film is formed in the trench.

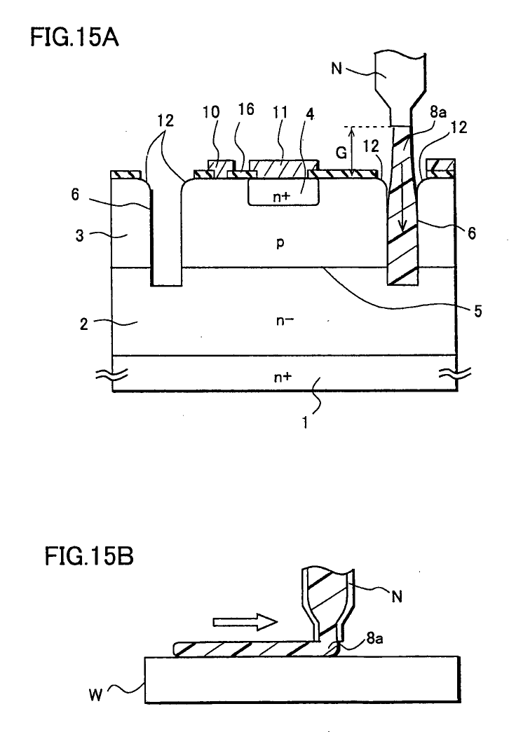

Specifically, refer to FIG. 15A. The photoresist film 17d is removed, and a passivation film 8 is applied. In this embodiment, a thermosetting resin paste 8a is injected and applied into the trench, whereby the passivation film is formed along the trench (mesa groove 6).

FIG. 15B is a schematic view showing injection-application of the thermosetting resin paste to a wafer W. Note that, FIG. 15B shows the application method of the thermosetting resin paste, and the dimensional scale of the wafer W and a nozzle N is different from the real one.

In this way, a dispenser (not illustrated) is disposed above the wafer W to have a predetermined gap G (for example, approximately 40 μm) therebetween. Then, the thermosetting resin paste 8a is filled into the dispenser. After that, the thermosetting resin paste 8a is injected and applied (dispensing-application) into the trench with a predetermined pressure while the nozzle N is being moved along the trench. In the plane pattern of the substrate, the trench is formed, for example, in a grid shape or a stripe shape, and the nozzle is moved along this.

The thermosetting resin paste is a thermosetting polyimide paste, for example. The viscosity of the thermosetting resin paste 8a is, for example, approximately 120 Pa·s.

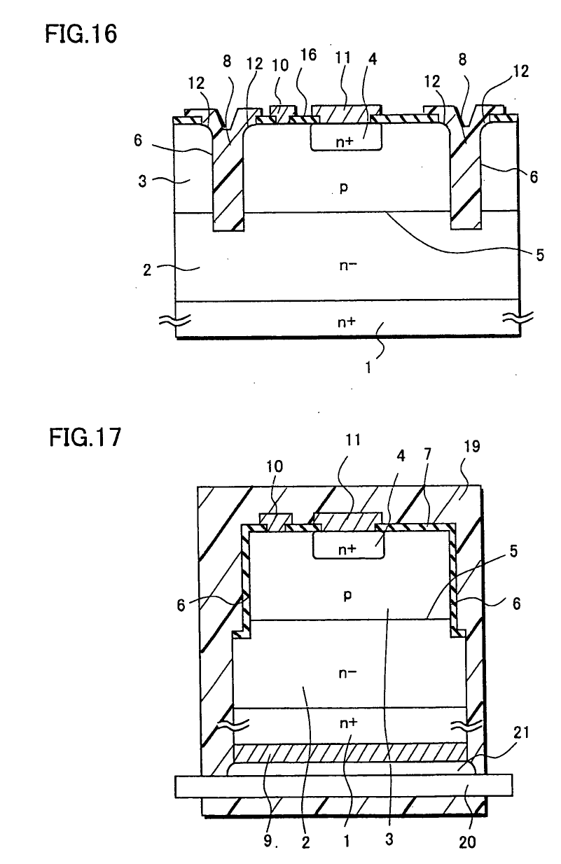

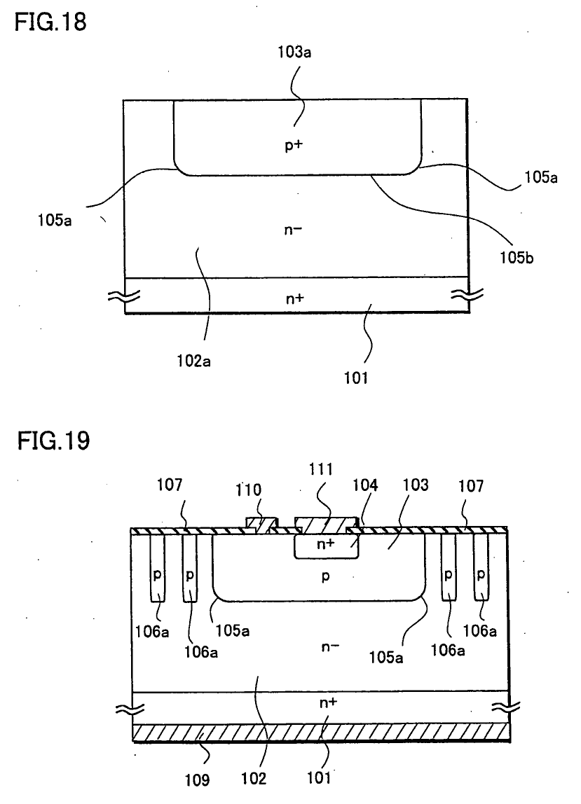

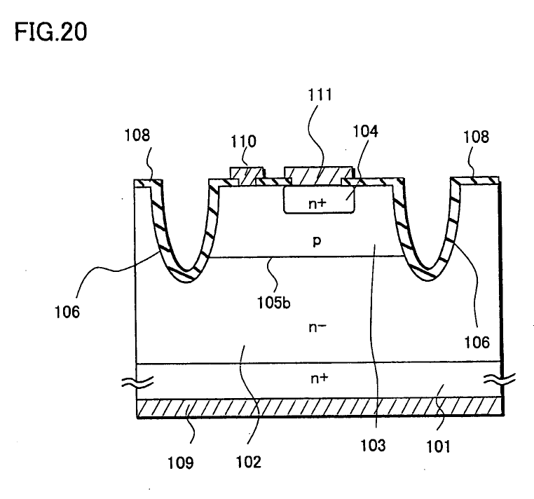

Thereafter, as shown in FIG. 16, thermosetting is performed to form the passivation film 8 buried in the mesa groove 6. Moreover, a metal layer is formed on the back surface of an n+ type semiconductor substrate 1, so that a collector electrode 9 is formed to obtain a structure shown in FIG. 3.

The mesa groove 6 of this embodiment is formed of a trench, so as to achieve miniaturization. In the case of such a mesa groove 6, if a glass paste is applied by spin coating (paste application) as in the conventional case, the inner portion is not sufficiently applied therewith, particularly when the mesa groove 6 is formed deep. For this reason, the passivation film does not function sufficiently in some case. Additionally, in the method of spin-coating a glass paste, the steps of drying, exposure, and development are required after the application, and the manufacturing process is complicated.

However, in this embodiment, the application is performed while the thermosetting resin paste is injected along the trench (see FIG. 15). Consequently, even if the mesa groove 6 is miniaturized and formed deep, the inner portion can also be applied sufficiently.

Moreover, the thermosetting resin paste is only required to be thermoset after the dispensing-application. Accordingly, the number of the manufacturing steps can be reduced, as compared with the conventional case of spin-coating a glass paste.

Furthermore, the upper shoulder portion 12 of the mesa groove 6 is formed with a gradual curvature. For this reason, the dispensing-application to the inside of the mesa groove 6 can be performed more easily, while the mesa groove 6 is preferably coated with the passivation film 8.

Note that, as another manufacturing method of the third embodiment, an upper shoulder portion 12 of a mesa groove 6 can be formed with a gradual curvature also by appropriately selecting the condition of wet etching for removing a damaged layer.

Specifically, in the second step of the third embodiment, a mask having an opening equal to the width of a trench is provided to perform anisotropic etching, so as to form the trench having a desired depth. Thereby, a structure shown in FIG. 13 is obtained. In this case, with regard to the depth of the trench, etching is performed to the desired depth of the mesa groove 6.

Thereafter, wet etching is performed to remove a damaged layer in the trench. At this time, as shown in FIG. 14, the upper shoulder portion 12 of the mesa groove 6 can be formed to have a shape with a predetermined curvature by appropriately selecting the condition of wet etching. In other words, the upper shoulder portion 12 of the mesa groove 6 is more easily exposed to the etching liquid than a bottom portion of the mesa groove 6, and thus the etching proceeds. As a result, the shape with a predetermined curvature is formed.

In this method, without performing additional anisotropic etching, it is possible to perform the processing of removing the damaged layer and chamfering the upper shoulder portion 12 of the mesa groove 6 in the single wet etching process.

As described above, in the manufacturing method of the semiconductor device according to this embodiment, the upper shoulder portion 12 of the mesa groove 6 is formed with a gradual curvature. For this reason, the mesa groove 6 is preferably coated with a passivation film 8. Thus, the mesa groove 6 is not required to be coated with a thermal oxide film 7 as in the first embodiment. Moreover, the mesa groove 6 has a mesa angle of 0° near a pn junction interface 5, in the same manner as the semiconductor device according to the first and second embodiments. Thus, an electric field concentration at an end portion of the pn junction interface 5 can be suppressed.

Note that, although not illustrated, in the manufacturing method of the third embodiment described above, the thermal oxide film 7 may be formed after the formation of the trench (mesa groove 6), and then a thermosetting resin paste 8a may be subjected to the dispensing-application as shown in FIG. 11A of the first embodiment.

In addition, the semiconductor device according to the third embodiment may be formed as described below.

Specifically, firstly, after the same first step performed as in the manufacturing method of the semiconductor device according to the first embodiment is performed, a structure shown in FIG. 10A is formed in the second step.

Next, as shown in FIG. 10B, a base region 3 is etched by the Bosch process by using a thermal oxide film 16 and a photoresist film 17c as a mask. Here, the Bosch process is a method in which a plasma etching process mainly using a SF₆ gas and a plasma deposition process mainly using a C₄F₈ gas are alternately repeated to maintain high etching selectivity, thereby enabling highly anisotropic etching. Thus, the substrate can be etched perpendicularly and deeply. Here, although not illustrated, by the Bosch process, a wavy unevenness exists on an inner wall surface of a mesa groove 6. The mesa groove 6 thus formed by the Bosch process is then dry-etched to flatten the inner wall of the mesa groove. At this time, the etching speed for an upper shoulder portion 12 of the mesa groove 6 is fast. Thus, because of the fast etching speed for the upper shoulder portion 12 of the mesa groove 6, this part is formed with a gradual curvature.

After that, the third step is performed as in the manufacturing method of the semiconductor device according to the third embodiment.

As described above, the mesa angle is made closer to 0° by using the Bosch process. Therefore, the Bosch process is suitably used for miniaturization and for higher breakdown voltage. Moreover, the mesa groove 6 formed by the Bosch process is further dry-etched, so that the inner wall of the mesa groove 6 is flattened and the upper shoulder portion 12 of the mesa groove 6 is formed with a gradual curvature, thereby improving the coating property of a passivation film 8.

Additionally, in the second embodiment, as shown in FIG. 17, when potting is performed with a resin 19 to mold the semiconductor device, the resin 19 functions as a passivation film, in the part of the mesa groove 6. This eliminates the need for the step of forming a passivation film 8 that coats the mesa groove 6 alone. Note that, in FIG. 17, a collector electrode 9 is mounted on an island portion 20 with a brazing material 21. However, the shape of the island portion 20 is appropriately changed depending on the type of the semiconductor device. Then, a base electrode 10 and an emitter electrode 11 are connected to a lead by an unillustrated wire or the like, for example.

Note that, it should be understood that the embodiments disclosed this time are all illustrative and not limitative. The scope of the present invention is defined not by the description of the above embodiments but by the scope of claims, and further includes meanings equal to the scope of claims and all changes within the scope.

For example, in the above embodiments, the description has been given of, as an example, a case where the semiconductor device is a bipolar transistor. However, the present invention is not limited to this. The present invention is similarly applicable to a case where the semiconductor device is a diode, a bipolar transistor, a MOSFET, or an IGBT. In other words, the present invention is similarly applicable, as long as a semiconductor device is required to achieve a high breakdown voltage and includes a pn junction in a film thickness direction of a semiconductor substrate.

Note that, an operating region AR in the case of the MOSFET includes: an n− type semiconductor layer 2 provided on an n+ type semiconductor substrate 1 and constituting a drain region together with the n+ type semiconductor substrate 1; and a p type semiconductor layer 3 serving as a channel region. Here, the operating region AR is configured of: a pn junction interface 5 therebetween; and a cell of a MOS transistor formed in the channel region 3.

In addition, an operating region AR in the case of the diode is configured of: an n− type semiconductor layer 2 serving as a cathode; a p type semiconductor layer 3 serving as an anode; and a pn junction interface 5 therebetween.

Moreover, in the first and the second embodiments, the mesa groove 6 is coated with the thermal oxide film 7 and the passivation film 8. However, the present invention is not limited to this, and the mesa groove 6 may be coated with only the thermal oxide film 7 depending on a desired breakdown voltage.

Furthermore, as shown in FIG. 1B, in the above embodiments, the mesa groove 6 is formed in a rectangular shape in a plan view. However, the present invention is not limited to this. For example, the four corners of the mesa groove 6 may be formed with a curvature in a plan view.
1 semiconductor substrate
2 first-conductivity-type semiconductor layer (collector region)
3 second-conductivity-type semiconductor layer (base region)
4 emitter region
5 pn junction interface
6 mesa groove
7 thermal oxide film
8 passivation film
9 collector electrode
10 base electrode
11 emitter electrode
12 upper shoulder portion
13 passivation film
14 mesa angle
15 electric-field concentration portion
16 thermal oxide film
17 photoresist film
18 electrode material
19 resin
20 island
21 brazing material
101 semiconductor substrate
102 collector region
102a low-concentration n type semiconductor layer
103 base region
103a high-concentration p type semiconductor layer
104 emitter region
105a curvature portion
105b flat end portion
106 mesa groove
106a guard ring
107 thermal oxide film
108 passivation film

1. A semiconductor device comprising:
a semiconductor substrate;
a first-conductivity-type semiconductor layer disposed on a front surface of the semiconductor substrate;
a second-conductivity-type semiconductor layer disposed on the first-conductivity-type semiconductor layer;
a first electrode disposed on a back surface of the semiconductor substrate; and
a second electrode disposed on the second-conductivity-type semiconductor layer,
wherein a trench is formed from the second-conductivity-type semiconductor layer into the first-conductivity-type semiconductor layer so as to define an operating region which includes a pn junction interface formed between the first-conductivity-type semiconductor layer and the second-conductivity-type semiconductor layer;
a sidewall of the trench comprises a side surface of the first-conductivity-type semiconductor layer and a side surface of the second-conductivity-type semiconductor layer, and
the sidewall is substantially perpendicular to the pn junction interface.

2. The semiconductor device according to claim 1, wherein the sidewall curves near a top surface of the second-conductivity-type semiconductor layer and is continuous with the top surface of the second-conductivity-type semiconductor layer.

3. The semiconductor device according to claim 1, wherein the sidewall is coated with a passivation film.

4. (canceled)

5. A manufacturing method of a semiconductor device, comprising:
providing a substrate comprising a first-conductivity-type semiconductor layer formed on a semiconductor substrate;
forming a second-conductivity-type semiconductor layer on the first-conductivity-type semiconductor layer;
performing an anisotropic etching to form a trench to define an operating region so that the trench reaches a part of the first-conductivity-type semiconductor layer from a top surface of the second-conductivity-type semiconductor layer; and
coating a sidewall of the trench with an insulating film.

6. The manufacturing method of claim 5, further comprising performing a wet etching to remove a top surface of the trench.

7. The manufacturing method of claim 6, wherein the wet etching is performed so that an upper shoulder portion of the trench is gradually curved.

8. The manufacturing method of claim 5, further comprising performing an additional anisotropic etching on the trench so that an upper shoulder portion of the trench is gradually curved.

9. The manufacturing method of claim 5, wherein the insulating film comprises a thermal oxide film formed by heat treatment.

10. The manufacturing method of claim 5, wherein the insulating film comprises a passivation film.

11. The manufacturing method of claim 9, further comprising performing molding with a resin to coat at least the trench.

12. The manufacturing method of claim 10, wherein a thermosetting resin paste is injected and applied along the trench to form the passivation film.

13. The manufacturing method of claim 9, further comprising forming a passivation film on the insulating film in the trench.

14. The semiconductor device according to claim 1, wherein the trench is cut in half in a direction substantially perpendicular to the pn junction.
